(19) United States
(12) Patent Application Publication
(10) Pub. No.: US 2023/0403940 A1
(43) Pub. Date: Dec. 14, 2023

(54) EXCITER ELEMENT

(71) Applicant: SPEKTRA SCHWINGUNGSTECHNIK UND AKUSTIK GMBH DRESDEN, Dresden (DE)

(72) Inventors: Martin IWANCZIK, Dresden (DE); Michael MENDE, Dresden (DE)

(21) Appl. No.: 18/246,709

(22) PCT Filed: Sep. 28, 2021
(86) PCT No.: PCT/EP2021/076615

§ 371 Date: Mar. 27, 2023

(30) Foreign Application Priority Data
Sep. 28, 2020 (EP) 20198602.3

(51) Int. Cl. H10N 30/88; H10N 30/20; B06B 1/06

(52) U.S. Cl. CPC H10N 30/88; H10N 30/20; B06B 1/0629

(57) ABSTRACT

An exciter element for generating or measuring mechanical movements with an exciter and a receptacle for an object under test and with an electrical inter-face for transmitting the excitation or measurement data and a method for producing such an exciter element, performs reliable measurement or generation in the event of mechanical movements above 100 kHz up to a few megahertz and permits both “out-of-plane” and “in-plane” movements or rotations of the DUT. A flat piezo composite, which is known per se, with a first face lying transverse to the direction of the plate thickness, a second face spaced apart from the first face by the thickness of the plate and lying parallel to the first face, and with rod-shaped piezo elements extending between the first and second face, is used as an exciter.

The invention relates to an exciter element for generating mechanical movements, having an exciter and a holder for an object to be tested, and having an electrical interface for transmission of the excitation or measurement data.

The invention relates also to a method for producing such an exciter element.

For the functional testing, characterization or calibration of sensors, in particular of vibration sensors, it is known to set them in vibration in a controlled, determined manner by way of a vibration exciter. The response of the sensor, as the test object or device under test (DUT), is then measured and information about the functional capability is obtained or values for calibration of the sensor are derived therefrom.

Calibration is defined as a comparative measurement of the measured variable of the DUT, wherein the measured variable of the DUT is related to a national standard. The deviation of the measured variable of the DUT from the correct value of the measured variable is determined and documented.

Functional testing is to be understood as meaning measurements which are carried out during various phases of the product (development, verification, service) in order to analyze the behavior of the DUT in respect of its measured variable beyond the scope of a calibration.

Characterization defines measurements in which not only is the DUT excited with its measured variable but in which the behavior of the DUT in response to interferences which may occur during its lifecycle is systematically investigated.

For the calibration of sensors, a vibration exciter of the applicant with the designation SE-09 is known, which is able to generate clean translational vibrations for calibrations in the frequency range up to 20 kHz. The vibration excitation here takes place by way of a purely electrodynamic vibration exciter, which is excited by way of an electrodynamic system, which is arranged in a casing. A base plate constitutes a counter-mass of the vibration system. The DUT is fastened to the vibration exciter. A disadvantage here is that the vibration frequency has an upper limit of 20 kHz. The vibration exciter can be used at up to 50 kHz for the functional testing and characterization of DUTs.

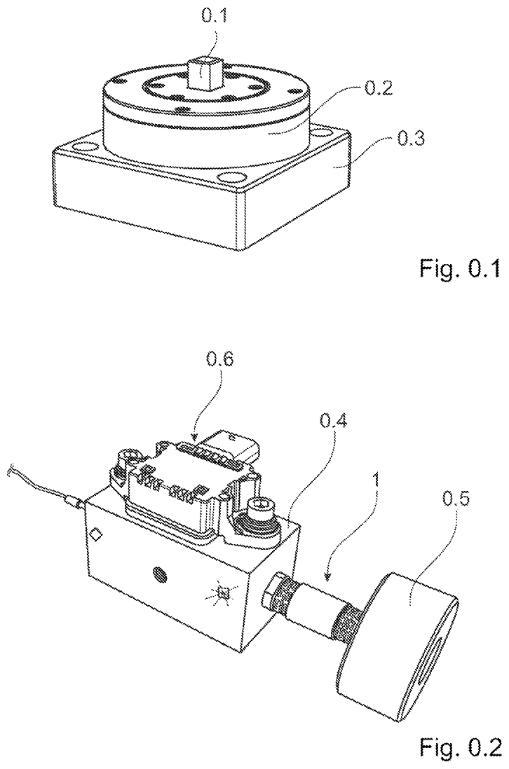

A vibration exciter with the designation SE-16, which is offered by the applicant himself, is known. This vibration exciter is shown in FIG. 0.1. The vibration excitation here takes place by way of a purely electrodynamic vibration exciter 0.1, which is excited by way of an electrodynamic system, which is arranged in a casing 0.2. A base plate 0.3 constitutes a counter-mass of the vibration system. The DUT is fastened to the vibration exciter 0.1. A disadvantage here is that the vibration frequency has an upper limit of 100 kHz owing to the principles involved. In addition, a clean translational vibration cannot be generated with this vibration exciter.

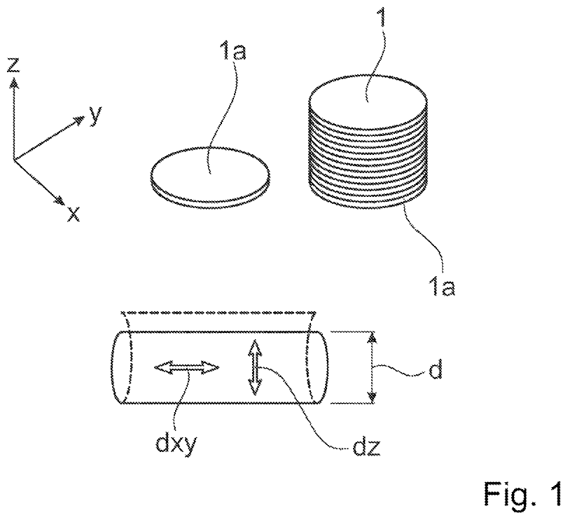

Also known is a vibration control system of the applicant with the designation VCS 401-Piezo having a piezo-based vibration exciter contained therein, as is shown in FIG. 0.2. A piezo oscillator 1, as is shown in FIG. 1, is used therein. The piezo oscillator 1 is arranged between the coupling member 0.4 and a counter-mass 0.5. The oscillator 0.4 is provided with a DUT holder for holding a test object 0.6 (sensor). The DUT holder is contained in the coupling member and here consists of two M6 internal threads.

However, this is only one variant of the design. The piezo oscillator thus consists of the piezo drive and two vibrating masses and thus forms a free dual-mass oscillator. One of the masses only has the function of a counter-mass (0.5), wherein the other mass (0.4) has the function of a coupling member to which a DUT can be fastened.

This piezo oscillator 1, as well as piezo oscillators that are available on the market, such as, for example, the piezoelectric shaker from piezosystems Jena (100 kHz, 5 μm, 1000 N), see https://www.piezosystem.com/products/piezocomposite/products/shaker/, consist of a stack of individual piezo vibrating plates 1a having a square, rectangular or round (as shown) base area and a thickness d. With such a stack of piezo vibrating plates 1a, a good translational movement can be achieved and few in-plane modes occur. However, even with this oscillator, vibration frequencies above 100 kHz cannot be generated, and the upper limit is given as 40 kHz in the datasheet. Although, here too, a vibration can still be generated above 40 kHz, it is no longer purely translational and thus no longer wholly controllable.

With the increasing use of sensors or actuators in numerous fields of application, which is made possible by miniaturized designs, in particular in microsystems with so-called MEMS (microelectromechanical system=MEMS), it is now necessary to test, to characterize and/or to calibrate MEMS sensors. However, MEMS actuators, that is to say components that actively generate movements, must also be tested, characterized and calibrated.

The known vibration exciters firstly have the disadvantage that, even if the physical limits are exploited as much as possible, the frequency range is limited, so that measurements of MEMS at higher frequencies, for example at 100 kHz to 3 MHz, are not possible. In addition, a movement of the DUT 3 is possible only in an out-of-plane direction 5. A movement in an in-plane direction 10, that is to say in which the movement axis 11 lies in the horizontal x-y direction, as is shown in the figures by arrows x, y and z, as well as a rotational movement about that movement axis is not possible. For the purpose of clear identification, the term “out-of-plane” is chosen for the z direction and “in-plane” for the x-y direction. The coordinate axes are indicated in the drawings.

Piezo plates with a nominal frequency of 2 MHz or more are available commercially. Such piezo oscillators are offered, for example, by PI Ceramic GmbH, 10 Lindenstraße, 07589 Lederhose. A problem here is the occurrence of in-plane modes over the entire frequency range, which generate uncontrollable out-of-plane movement.

Single piezo vibrating plates 1a, as shown in FIG. 1, have the disadvantage that, in the case of a longitudinal excitation dz, pronounced transverse excitation dxy is also to be observed, which leads to uncontrolled movement of the plate. As already described, a good translational movement can be achieved with a stack of piezo vibrating plates 1a, and few in-plane modes occur. However, even with such an oscillator, it is not possible to generate vibration frequencies above a few kHz to a few megahertz. A uniform translation in the “out-of-plane” direction 5 is possible only in selected frequency ranges, and “in-plane” movements occur, as described above, but are not excitable in a controllable manner since they occur only as a side-effect, or coupled effect, of the out-of-plane movement. Rotation of a DUT fastened to the piezo oscillator, or rotation of the DUT, is not possible at all.

Acoustic signal generators in the form of a piezo composite 12, as is shown in FIG. 3 to FIG. 5, are known from acoustics, in particular from acoustic measurement technology. The piezo composite is also a plate, as explained in relation to FIG. 1, but it is divided into a plurality of n piezo elements 13. The piezo elements 13 are connected together by means of a matrix 14. The advantage compared to a standard piezo plate, as is to be seen in a piezo oscillator 1, consists in that it exhibits a significantly less pronounced transverse excitation dxy. However, a use of an acoustic sound source as a piezo oscillator 1 in a measuring or calibration assembly 2 is not known.

The object underlying the invention is to provide an exciter element for generating or measuring mechanical movements, having an exciter and a holder for an object to be tested, and having an electrical interface for transmission of the excitation or measurement data, which exciter element works reliably in the case of mechanical movements above one kHz, in particular above 40 kHz and preferably above 100 kHz up to an order of magnitude of several 10 megahertz, and permits both “out-of-plane” movements and rotations of the DUT.

This object is achieved, at the assembly, in that there is used as the exciter a piezo vibrating plate or a piezo oscillator in the form of a piezo composite having a first face lying transverse to the direction of the plate thickness, a second face spaced apart from the first face by the plate thickness and lying parallel to the first face, and having rod-like piezo elements extending between the first and second faces. The exciter is provided on its first face with a first contact surface and on its second face with a second contact surface, wherein the contact surfaces are activatable. The exciter is configured to hold an object to be tested on its second face.

With such an assembly, it is in principle possible for the first time to reliably generate mechanical movements in a frequency range from above one kHz, in particular above 40 kHz and preferably above 100 kHz, up to an order of magnitude of several 10 megahertz.

In one embodiment of the invention it is provided that there is used as the exciter a plate-shaped piezo composite known per se having a first face lying transverse to the direction of the plate thickness, a second face spaced apart from the first face by the plate thickness and lying parallel to the first face, and having rod-like piezo elements extending between the first and second faces, and the exciter is subdivided into segments of piezo elements which are configured to be excitable separately.

In addition to the significantly less pronounced transverse excitation dxy, it is also possible to configure partitions in particular in a customized manner.

For the excitation of individual partitions, for the purposive control of individual partitions, for the suppression of plate modes and/or for the excitation of rotation by phase shift between partitions, it is provided that the exciter is provided on its first face with a first segmented contact surface and on its second face with a second segmented contact surface, wherein the contact surfaces are activatable segment-wise and separately from one another by way of the interface. The exciter is configured to hold an object to be tested on its second face.

In order to produce the partitions, it is provided that the two contact surfaces are segmented in strip form, wherein each contact strip has the same width.

If partitions in strip form are to be produced, the contact strips of the two contact surfaces can have the same orientation in the horizontal direction, that is to say in the x or y direction.

It is, however, also possible to produce insular partitions in that the contact strips on the first contact surface have an orientation in a first horizontal direction, that is to say x direction, and on the second contact surface have a direction lying in a second direction orthogonal to the first horizontal direction, that is to say y direction. The cut surfaces, seen in a projection in the vertical z direction, of the contact strips of the first and second contact surfaces here constitute the insular partitions.

Preferably in respect of the configuration that the exciter is able to hold an object to be tested on its second face, it is provided that the exciter is provided over the second contact surface with a segmented coupling plate. The segmentation of the coupling plate serves to reproduce the partitions of the exciter, that is to say the segmentation is preferably so chosen that the cut surfaces, seen in a projection in the vertical z direction, of the contact strips of the first and second contact surfaces form the partitions, which correspond with the segments, so that movements of the segments or movements of the partitions can in each case be transmitted.

In one embodiment of the exciter element it is provided that the coupling plate is segmented into first coupling plate segments of strip form, such that the width and direction thereof correspond to the contact strips of the second contact surface, and the first coupling plate segments are oriented in the y direction and lie above the contact strips of the second contact surface in the vertical z direction. Partitions of strip form are thus produced. These can be excited individually by application of a voltage to the contact strips lying opposite one another in the Z projection. Accordingly, all translational movements in the Z direction of the individual partitions are possible separately from one another. It is thus possible to produce translations of the exciter element as a whole, as well as wave-like movements and the like. However, it is also possible for the first time to produce rotations of the DUT about a rotation axis which lies in the plane lying in the x-y direction by activation, phase-shifted by 180°, of adjacent partitions or of adjacent groups of partitions.

In a further embodiment of the exciter element according to the invention it can be provided that the coupling plate is additionally segmented into strips running in the x direction to form square second coupling plate segments, and the square second coupling plate segments, when the contact strips of the first and second contact surfaces are oriented orthogonally to one another, lie in the vertical z direction above cut surfaces, seen in the vertical z direction, of the contact strips of the first and second contact surfaces. Insular partitioning is thus achieved. Contact strips that intersect in the projection can be contacted individually. The piezo elements lying in the cut regions of the respective contact strips are excited on application of a voltage. However, it continues to be possible also to excite entire strips or groups, as described above.

In a preferred embodiment it is provided that the first or second coupling plate segments are mechanically connected adjacently to one another by means of a connecting means. The connecting means can be in the form of:
weakening of the structure in that region and an associated reduction in stiffness
filling material having a lower modulus of elasticity than the coupling plate segment.

The coupling plate segments are thus able to move independently of one another at least in the frequency range that comes into consideration here.

The connecting means can consist of epoxy resin, silicone or another plastics material. These are materials that effect mechanical decoupling of the coupling plate segments in the frequency range.

One purpose is mechanical decoupling. Another purpose is to achieve a sufficiently strong hold between the coupling plate segments during manufacture.

By means of the connecting means, a smooth surface of the coupling plate, to which the DUT can be applied, preferably adhesively bonded, is achieved. In particular easily reversible adhesives can be used here, which can be removed from the DUT without leaving a residue and without damaging it, so as to allow further use of the DUT and also of the exciter.

It should be emphasized here that what matters with the exciter element described here is a mechanical coupling between the DUT and the exciter element and not an acoustic coupling, as corresponds to the actual purpose of the piezo composite.

In order not only to ensure a better connection of the DUT with the coupling plate, but also to produce a vibration system in the form of a free dual-mass oscillator, the exciter is connected at its first contact surface to a counter-mass. The coupling plate elements on one face thus act as a mass of the vibration system, and the counter-mass on the other face acts as a second mass of the vibration system.

For the further configuration and production of individual dual-mass oscillators to form a dual-mass oscillator array, it is provided that the counter-mass is in the form of a counter-mass plate, which is structured into counter-mass segments corresponding to the coupling plate, wherein the thickness of the counter-mass plate can differ from the thickness of the coupling plate. It is also conceivable that DUT are also fastened to the first face.

In a further embodiment it is provided that the exciter element is fastened to a second vibration exciter. This second vibration exciter can be, for example, an electrodynamic vibration exciter as is known from the prior art, for example an SE-16 of the applicant. It is thus possible to cover a low frequency range, in which the second vibration exciter is able to work, by the second vibration exciter and to cover higher frequencies above the reliable working range of the second vibration exciter by the exciter element according to the invention.

The object according to the invention is also achieved by a method for producing an exciter element. The coupling plate, at a distance and with a direction corresponding to those of the coupling plate segments, is here provided from its second or first face with a recess. However, the recess does not reach as far as the respective other second or first face but only as far as a distance from the opposing first or second face. The recess is then filled with the connecting means. For separation of the coupling plate elements, the coupling plate on the respective opposing first or second face is removed until the recess is reached.

The coupling plate can be connected to the exciter, for example by adhesive bonding. The connection is made in such a way that multiple exciter elements, in particular one or more piezo segments, are located opposite a coupling plate segment. The multiple exciter elements are accordingly responsible for the excitation of the DUT in the region of the coupling plate element or for the detection of an action of the DUT in the region of the respective coupling plate element.

In order to produce a vibration system, it is provided that the exciter is connected to the counter-mass plate and the counter-mass plate is structured in the manner of the coupling plate. There are thus formed individual small dual-mass oscillators having the size of the partitions, which are activatable individually according to the invention, so that a wide variety of movement forms of the DUT can be generated, such as translational movements and/or rotational movements, in particular tilting movements and/or wave-like movements.

In particular, rotational movements about a rotation axis lying in the in-plane direction can be generated, if, for example, adjacent partitions are activated in opposite directions.

The invention will be explained in greater detail below by means of an exemplary embodiment. In the drawings

FIG. 0.1 shows a vibration exciter SE-16 of the applicant,

FIG. 0.2 shows a piezo-based vibration exciter as part of the vibration control system VCS401-piezo of the applicant,

FIG. 1 shows a standard piezo oscillator in different structural forms with its vibration behavior,

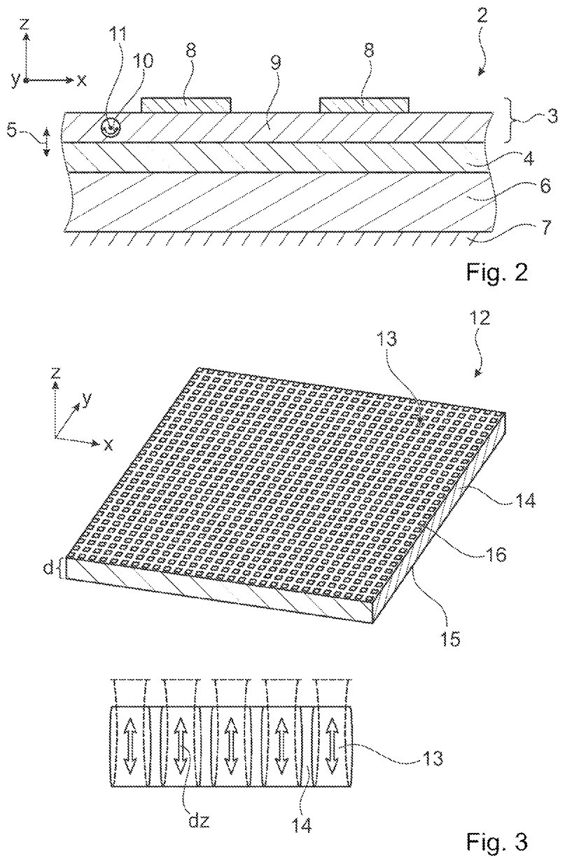

FIG. 2 shows a basic setup according to the invention of a measuring or calibration assembly,

FIG. 3 is a perspective view and a cross-sectional view of a piezo composite,

FIG. 4 shows an enlarged detail of a perspective view of a piezo composite,

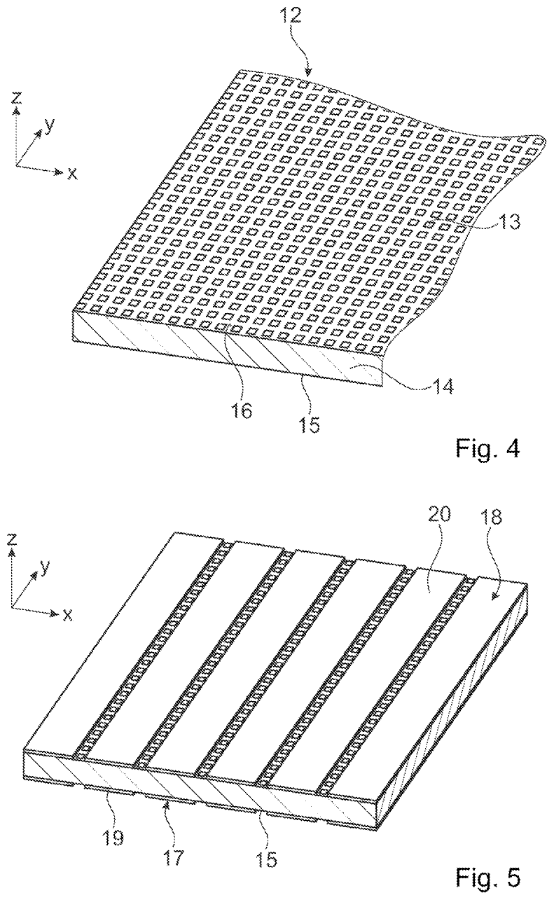

FIG. 5 shows a piezo composite with contact strips,

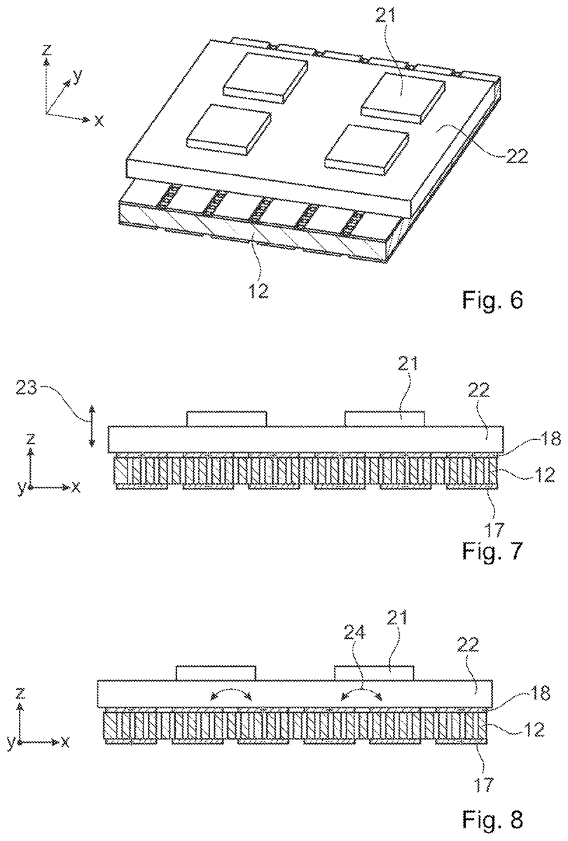

FIG. 6 is a perspective view of a piezo composite with a DUT arranged thereon,

FIG. 7 shows a cross-section through the piezo composite of FIG. 6 with a DUT arranged thereon and an applied voltage for a translational excitation,

FIG. 8 shows a cross-section through the piezo composite of FIG. 6 with a DUT arranged thereon and an applied voltage for a rotational excitation,

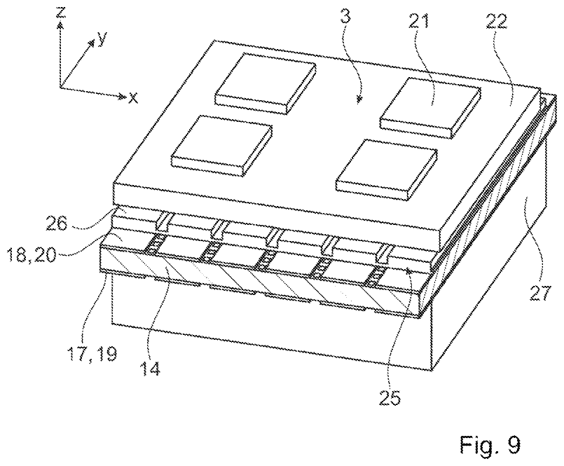

FIG. 9 is a perspective view of a piezo composite with a coupling plate in strip form and a DUT arranged on the second face thereof,

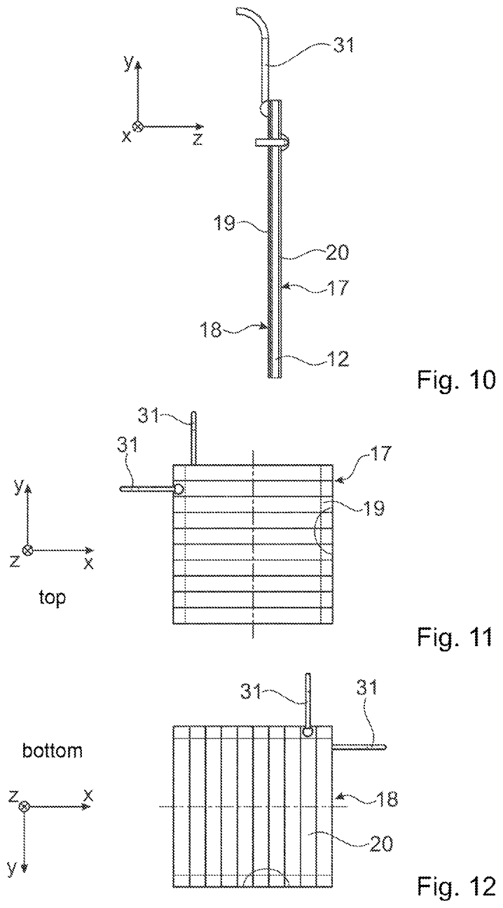

FIG. 10 is a side view of a piezo composite provided with contact strips on the first face in the y direction and with contact strips on the second face in the y direction,

FIG. 11 is a plan view of a piezo composite provided with contact strips on the second face in the x direction,

FIG. 12 is a plan view of a piezo composite provided with contact strips on the first face in the y direction,

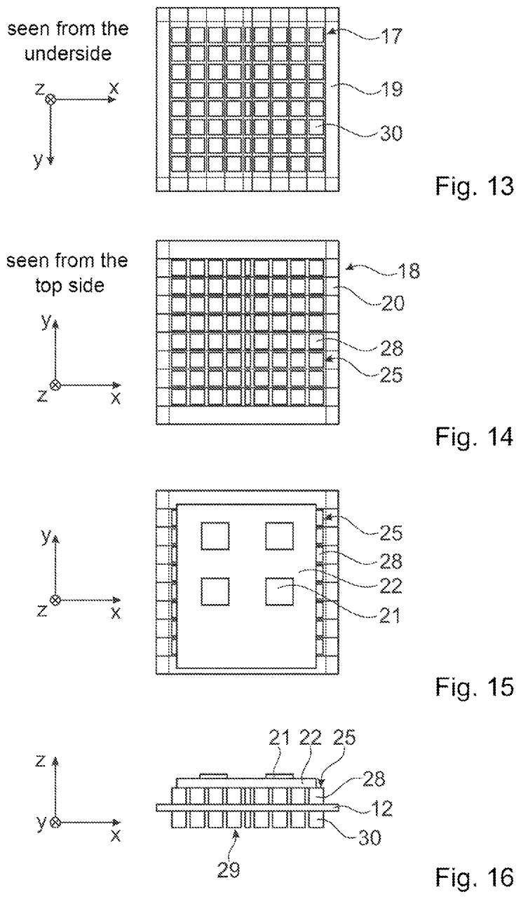

FIG. 13 is a plan view of a piezo composite provided with contact strips on the first face and in the y direction of a structured counter-mass plate,

FIG. 14 is a plan view of a piezo composite provided with contact strips on the second face in the x direction and a structured mass plate,

FIG. 15 is a plan view of an exciter element provided with a DUT on the second face,

FIG. 16 is a cross-section through a piezo composite provided with a structured mass plate, a structured counter-mass plate and a DUT, and

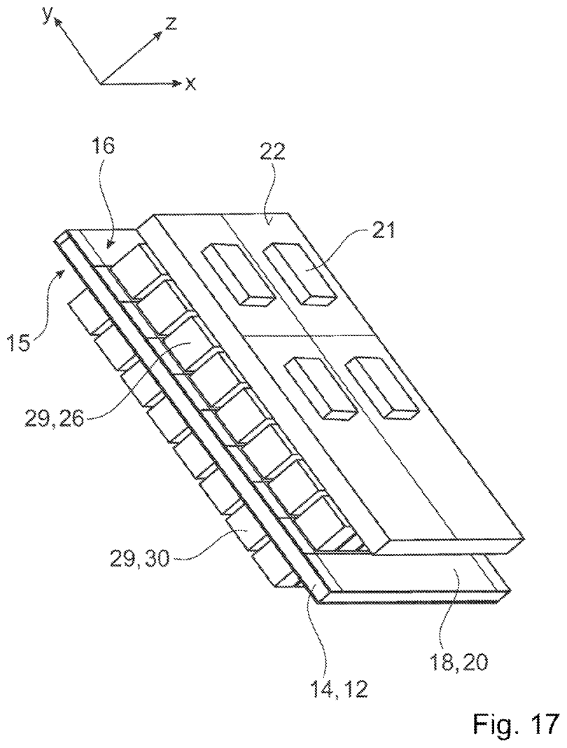

FIG. 17 is a perspective view of a piezo composite according to FIG. 16.

FIG. 2 shows a basic setup of a DUT 3 on a measuring and calibration assembly 2. A DUT (device under test=DUT) 3, which is arranged on an oscillator 4 and is thereby set in mechanical movements in a vertical or “out-of-plane” direction 5, is to be tested. The oscillator 4 is connected to a counter-mass 6, which can be connected resiliently or fixedly to a counter-mass 7.

Such DUTs 3 consist of one or more movement elements 8 in the form of MEMS, which can be in the form of sensors or actuators, and a control electronics, which are arranged on a support 9 (in the form of a printed circuit board (PCB) or a chip). The sensors may be, for example, inertial sensors (acceleration and rotation sensors) and the actuators may be, for example, optical actuators (e.g. mirror actuators), fluidic actuators (e.g. valves or pumps) or acoustic actuators (e.g. sound sources).

This microsystem, consisting of movement elements 8 in the form of MEMS and the support 9 in the form of a PCB, is arranged on an exciter element 4. The exciter element is configured in accordance with the prior art as an oscillator, which is capable of setting the microsystem 3 as the DUT in translational vibrations, following which the response of the DUT 3 to the vibrations is measured. It is not known to measure actions of a DUT 3, that is to say when the DUT 3 contains an actuator as the movement element 8, using such a setup.

A basic idea of the invention is to use as the exciter in an exciter element 4 according to FIG. 2 for generating or measuring mechanical movements a piezo composite 12 according to FIG. 3 and FIG. 4 which is known per se and has a first face 15, a second face 16 spaced apart by a thickness d from the first face 15, and which has rod-like piezo elements 13 extending between the first face 15 and the second face 16.

As is shown in FIG. 5, the piezo composite 12 is provided on its first face 15 with a first segmented contact surface 17 and on its second face 16 with a second segmented contact surface 18, wherein the contact surfaces 17 and 18 are activatable segment-wise and separately from one another by way of an interface formed of contacts 31, as are shown in FIGS. 10 to 12.

The two contact surfaces 17 and 18 are segmented in strip form, in each case into contact strips 19 of the first contact surface 17 and contact strips 20 of the second contact surface 18, wherein each of the contact strips 19 and 20 preferably but not necessarily has the same width.

There are two possibilities for orienting the contact strips 19 and 20.

As is shown in FIG. 6, the piezo element 13 provided with the contact surfaces 17 and 18 can be equipped with a DUT 3, preferably a PCB with a MEMS. In the example, the DUT 3 contains four MEMS 21, which are arranged on a PCB 22.

The contact strips 19 and 20 of the two contact surfaces 17 and 18 can have the same orientation in the horizontal direction, that is to say in the x or y direction.

FIG. 7 shows that, by applying an equal voltage to the first contact surface 17 and a voltage with a different polarization to the second contact surface 18, a translational movement 23 can be generated.

FIG. 8 shows that, by applying a different voltage to the first contact surface 17 and a different voltage with a different polarization to the second contact surface 18, a rotational movement 24 can be generated.

As is shown in FIG. 9, the piezo composite 12 as an embodiment of the exciter is provided over the second contact surface 18 with a segmented coupling plate 25.

This segmented coupling plate 25 constitutes a holder for the DUT 3.

The coupling plate 25 is segmented into first coupling plate segments 26 of strip form, such that their width and direction correspond to the contact strips 20 of the second contact surface 18 and the first coupling plate segments 26 are oriented in the y direction and lie above the contact strips 20 of the second contact surface 18 in the vertical z direction.

The piezo composite 12 is connected at its first face to a counter-mass 27.

As is shown in FIG. 10 to FIG. 12, in another embodiment the contact strips 19 on the first contact surface 17 can have an orientation in a first horizontal direction, that is to say x direction, and on the second contact surface 18 can have a direction lying in a second direction orthogonal to the first horizontal direction, that is to say y direction. In the figures, the contacts 31 are shown only schematically. Usually, all the contact strips 19 and 20 are provided with contacts 31. Inclined forms or annular or other forms of the contact strips are not shown but are also possible.

Thus, with the application of a voltage, the piezo elements 13 in the intersecting regions of the contact strips 19 and 20 can each purposively be excited or measured, analogously to the application of a voltage in FIG. 7 and FIG. 8.

The coupling plate 25 can additionally be segmented into strips running in the x direction to form square second coupling plate segments 28, and the square second coupling plate segments 28, when the contact strips 19 and 20 of the first and second contact surfaces 17 and 18 are oriented orthogonally to one another, lie in the vertical z direction above cut surfaces, seen in a projection in the vertical z direction, of the contact strips 19 and 20 of the first and second contact surfaces 17 and 18.

The first or second coupling plate segments 26, 28 are mechanically connected adjacently to one another by means of a connecting means, wherein the modulus of elasticity of the connecting means is lower than that of the coupling plate segments. The connecting means can consist of epoxy or silicone. Furthermore, by corresponding shaping, decoupling can also be achieved, for example by means of a narrow web, as shown by reference sign 26 in FIG. 9.

As is shown in FIG. 13 and FIG. 17, the counter-mass 27 is in the form of a segmented counter-mass plate 29, which is structured into counter-mass segments 30 corresponding to the coupling plate 25.

This is produced in that the coupling plate 25 and/or the counter-mass plate 29, at a distance and with a direction corresponding to those of the coupling plate segments 26 or of the counter-mass elements 30, is provided from its first or second face with a recess, wherein the recess does not, however, reach as far as the respective other second or first face but only as far as a distance from the opposing first or second face, the recess is filled with a connecting means, and the coupling plate 25 or the counter-mass plate 29 on the respective opposing first or second side is removed until the recess is reached.

### Exciter Element

### LIST OF REFERENCE SIGNS

0.1 vibration exciter
0.2 casing
0.3 base plate
0.4 oscillator
0.5 counter-mass
0.6 DUT holder
1 piezo oscillator
1a piezo vibrating plate
2 measuring or calibration assembly
3 microsystem, DUT
4 exciter element, oscillator
5 “out-of-plane” direction
6 counter-mass
7 base mass
8 movement element, MEMS
9 support, PCB
10 “in-plane” movement
11 movement axis
12 piezo composite
13 piezo element
14 matrix
15 first face
16 second face
17 first segmented contact surface on the first face
18 second segmented contact surface on the second face
19 contact strip of the first contact surface
20 contact strip of the second contact surface
21 MEMS
22 PCB
23 translational movement
24 rotational movement
25 segmented coupling plate
26 first coupling plate segment in strip form
27 counter-mass
28 square second coupling plate segment
29 segmented counter-mass plate
30 counter-mass segment
31 contact

1. An exciter element for generating mechanical movements, having an exciter and a holder for an object to be tested, and having an electrical interface for transmission of the excitation or measurement data, comprising
a piezo vibrating plate or a piezo oscillator in the form of a piezo composite having a first face lying transverse to the direction of the plate thickness, a second face spaced apart from the first face by the plate thickness and lying parallel to the first face, and having piezo elements between the first and second faces,
a first contact surface provided on the first face and a second contact surface on the second face, wherein the contact surfaces are activatable,
wherein the exciter is configured to hold an object to be tested on its second face.

2. The exciter element as claimed in claim 1, wherein the exciter comprises a plate-shaped piezo composite having a first face lying transverse to the direction of the plate thickness, a second face spaced apart from the first face by the plate thickness and lying parallel to the first face, and having rod-like piezo elements extending between the first face and the second face, and the exciter is subdivided into segments of piezo elements which are configured to be excitable separately.

3. The exciter element as claimed in claim 2, wherein the exciter is provided on its first face with a first segmented contact surface and on its second face with a second segmented contact surface, wherein the contact surfaces are activatable segment-wise and separately from one another by way of the interface.

4. The exciter element as claimed in claim 1, characterized in that wherein the two contact surfaces are segmented in strip form, wherein each contact strip has the same width.

5. The exciter element as claimed in claim 1, wherein the contact strips of the two contact surfaces have the same orientation in the horizontal direction, that is to say in the x or y direction.

6. The exciter element as claimed in claim 1, wherein the contact strips on the first contact surface have an orientation in a first horizontal direction, that is to say x direction, and the contact strips on the second contact surface have a direction lying in a second direction orthogonal to the first horizontal direction, that is to say y direction.

7. The exciter element as claimed in claim 1, wherein the exciter is provided over the second contact surface with a segmented coupling plate.

8. The exciter element as claimed in claim 7, wherein the coupling plate is segmented into first coupling plate segments of strip form, such that the width and direction thereof correspond to the contact strips of the second contact surface, and the first coupling plate segments are oriented in the y direction and lie above the contact strips of the second contact surface in the vertical z direction.

9. The exciter element as claimed in claim 8, wherein the coupling plate is additionally segmented into strips running in the x direction to form square second coupling plate segments, and the square second coupling plate segments, when the contact strips of the first and second contact surfaces are oriented orthogonally to one another, lie in the vertical z direction above cut surfaces, seen in a projection in the vertical z direction, of the contact strips of the first and second contact surfaces.

10. The exciter element as claimed in claim 7, wherein the first coupling plate segments or second coupling plate segments are mechanically connected adjacently to one another by means of a connecting means, wherein the modulus of elasticity of the connecting means is less than that of the coupling plate segments.

11. The exciter element as claimed in claim 10, wherein the connecting means comprises epoxy resin, silicone or another plastics material.

12. The exciter element as claimed in claim 1, wherein the exciter is connected at its first face to a counter-mass.

13. The exciter element as claimed in claim 12, wherein the counter-mass is in the form of a counter-mass plate, which is structured into counter-mass segments corresponding to the coupling plate.

14. The exciter element as claimed in claim 1, wherein the exciter element is fastened to a second vibration exciter.

15. A method for producing an exciter element as claimed in claim 1 wherein the coupling plate, at a distance and with a direction corresponding to those of the coupling plate segments, is provided from its second or first face with a recess, wherein the recess does not, however, reach as far as the respective other second face or first face but only as far as a distance from the opposing first face or second face, the recess is filled with the connecting means, and the coupling plate on the respective opposing first or second face is removed until the recess is reached.

16. The method as claimed in claim 15, wherein the coupling plate is connected to the exciter, such that multiple exciter elements are located opposite a coupling plate segment.

17. The method as claimed in claim 17, wherein the exciter is connected to the counter-mass plate and the counter-mass plate structured in the manner of the coupling plate.

18. The exciter element as claimed in claim 9, wherein the first coupling plate segments or second coupling plate segments are mechanically connected adjacently to one another by means of a connecting means, wherein the modulus of elasticity of the connecting means is less than that of the coupling plate segments.

19. The exciter element as claimed in claim 18, wherein the exciter is connected at its first face to a counter-mass.

20. The exciter element as claimed in one of claim 19, wherein the exciter element is fastened to a second vibration exciter.
